(19) United States
(12) Patent Application Publication
(10) Pub. No.: US 2013/0160849 A1
(43) Pub. Date: Jun. 27, 2013

(54) POLYCRYSTALLINE SILICON SOLAR CELL PANEL AND MANUFACTURING METHOD THEREOF

(71) Applicant: PANASONIC CORPORATION, Osaka (JP)

(72) Inventors: HITOSHI YAMANISHI, Osaka (JP); ICHIRO NAKAYAMA, Osaka (JP); TOMOHIRO OKUMURA, Osaka (JP)

(73) Assignee: PANASONIC CORPORATION, Osaka (JP)

(21) Appl. No.: 13/719,420

(22) Filed: Dec. 19, 2012

(30) Foreign Application Priority Data
Dec. 22, 2011 (JP) 2011-280924
Sep. 25, 2012 (JP) 2012-210820

(51) Int. Cl. H01L 31/0368; H01L 31/20

(52) U.S. Cl. CPC H01L 31/03682; H01L 31/20
USPC 136/258; 438/97

(57) ABSTRACT

An inexpensive polycrystalline silicon solar cell panel is provided by forming a polycrystalline silicon film in which pn junctions are formed by using fewer processes and in less time. Specifically, there is provided a manufacturing method for a polycrystalline silicon solar cell panel including: a process of forming an amorphous silicon film on a substrate surface using a vapor deposition method that uses an n-type or p-type doped vapor deposition material formed of silicon; a process of plasma-doping a surface layer of the amorphous silicon film with a p-type or n-type dopant; and a process of melting the amorphous silicon film by scanning the plasma-doped amorphous silicon film with plasma and performing re-crystallization.

This application is entitled to the benefit of Japanese Patent Applications No. 2011-280924, filed Dec. 22, 2011, and No. 2012-210820, filed Sep. 25, 2012.

1. Technical Field

The present invention relates to a polycrystalline silicon solar cell panel and manufacturing methods thereof.

2. Background Art

Crystalline silicon solar cells can mainly be classified into monocrystalline silicon solar cells and polycrystalline silicon solar cells. Generally, in crystalline silicon solar cells, as shown in FIG. 4A, an n-type or p-type doped silicon ingot 30 is cut with wire 31, sliced to a thickness of approximately 200 μm using a dicing technique and the sliced ingot is used as a silicon plate that constitutes the main body of a solar cell (refer to PTL 1).

The silicon ingot may be a monocrystalline silicon ingot produced by the Czochralski method or the like, or may be a polycrystalline silicon ingot produced by a method referred to as a casting method in which a molten silicon mold is solidified. Generally, the size of the silicon ingot is 300 mm in diameter for a monocrystalline silicon ingot and although the shapes thereof differ, polycrystalline silicon ingots are substantially the same size. Accordingly, it is difficult to obtain a large-sized silicon plate or silicon film from a silicon ingot.

Meanwhile, as a method of manufacturing a polycrystalline silicon film for a polycrystalline solar cell, a method of melting and polycrystallizing silicon particles deposited on a support substrate is known (refer to PTL 2). An apparatus for manufacturing a polycrystalline silicon plate is illustrated in FIG. 5A. Silicon particles 42 (20 nm or less) generated by irradiating silicon anode 40 with arc discharge 41, carried by argon gas 43, are deposited on support substrate 45 through transport pipe 44, then silicon particles 42 deposited on support substrate 45 are irradiated with high-temperature plasma 46 to be melted, annealing is performed with halogen lamp 47 to configure a polycrystalline silicon plate and support substrate 45 and polycrystalline silicon plate 49 are separated in separation chamber 48.

As methods of manufacturing a polycrystalline silicon film for a polycrystalline solar cell, polycrystallizing an amorphous silicon film formed using vacuum vapor deposition, a catalytic chemical vapor-phase deposition (Cat-CVD) method, glow discharge decomposition, a plasma CVD method, a sputtering method or the like have been examined. Examples of such methods will be mentioned below.

For example, a method in which an amorphous silicon film formed on a glass substrate using a catalytic chemical vapor-phase deposition (Cat-CVD) method, is polycrystallized with a high-energy beam (a flashlamp) has also been examined (refer to PTL 3 and NPL 1). More specifically, after forming a Cr film to be an electrode, on respective quartz substrates of 20 mm, a 3 μm amorphous silicon film is formed using a Cat-CVD method and the amorphous silicon film is polycrystallized by performing a heat treatment with a flashlamp (treatment time: 5 ms).

In addition, forming semiconductor junctions has been reported, in which an amorphous silicon film formed using a vacuum vapor deposition method is polycrystallized to be a polycrystalline film, an ion injection into the surface of the polycrystalline film is performed, and further annealing is performed (refer to PTLs 4 and 5).

Additionally, a flow of forming a laminated body of an n-type or p-type first amorphous silicon layer and an undoped second amorphous silicon layer using a CVD method or a plasma CVD method and thermally annealing the laminated body with plasma that contains either a p-type or an n-type dopant source has been proposed (refer to PTL 6). In addition to polycrystallizing the amorphous silicon layers that configure the laminated body, the thermal annealing forms pn junctions.

Furthermore, a process including a step of forming a first semiconductor layer having a first conductivity type with a high frequency plasma CVD method, a step of forming an i-type semiconductor layer with a microwave plasma CVD method, and a step of forming a second semiconductor layer having an opposite conductivity type to the first conductivity type by plasma-doping the i-type semiconductor layer formed by the microwave plasma CVD method, has been reported (refer to PTLs 7 and 8).

A process of polycrystallizing and doping an amorphous silicon film by irradiating an amorphous silicon film formed by a sputtering method, a vapor deposition method, or a PECVD method in dopant gas with a pulse laser has also been reported (refer to PTL 9).

Meanwhile, in a method of manufacturing a p-i-n device structure for LEDs, a technique of obtaining a laminated body that includes a first hydrogenated amorphous silicon alloy layer, an i-type hydrogenated amorphous silicon alloy layer and a second hydrogenated amorphous silicon layer by performing RF glow discharge decomposition, and then polycrystallizing the first hydrogenated amorphous silicon alloy layer and the second hydrogenated amorphous silicon layer using a scanning laser (refer to PTLs 10 and 11).

### CITATION LIST

### Patent Literature

### PTL 1: Japanese Patent Application Laid-Open No. 2000-263545

### PTL 2: Japanese Patent Application Laid-Open NO. HEI6-268242

### PTL 3: Japanese Patent Application Laid-Open No. 2008-53407

### PTL 4: Japanese Patent Application Laid-Open NO. HEI7-312439

PTL 5: U.S. Pat. No. 5,584,941

### PTL 6: Japanese Patent Application Laid-Open NO. HEI7-335660

### PTL 7: Japanese Patent Application Laid-Open NO. HEI6-232432

PTL 8: U.S. Pat. No. 5,589,007
PTL 9: U.S. Pat. No. 5,456,763

### PTL 10: Japanese Patent Application Laid-Open NO. HEI4-302136

PTL 11: U.S. Pat. No. 5,162,239

### Non-Patent Literature

NPL 1: Proceedings of the 54th Meeting of the Japan Society of Applied Physics; “Uniform crystallization in thin amorphous silicon film surface using flashlamp annealing”.

### SUMMARY OF INVENTION

### Technical Problem

As discussed above, a variety of techniques for producing crystalline silicon films or crystalline silicon plates in order to manufacture crystalline silicon solar cells, have been examined. Reducing the manufacturing costs of polycrystalline silicon films or polycrystalline silicon plates could be considered as first means for reducing the manufacturing costs of crystalline silicon solar cells.

Generating high purity silicon particles by irradiating a silicon anode with arc as disclosed in PTL 2 described above is a possibility, but it is difficult to control the size of the silicon particles. Therefore, it is difficult to improve the characteristics of a solar cell including a polycrystalline silicon film obtained through such a process. Furthermore, complicated manufacturing equipment is required to deposit silicon particles on a substrate in a uniform and homogenous manner.

In addition, a method of polycrystallizing an amorphous silicon film prepared using a CVD method (a Cat-CVD method, a plasma CVD method or the like) as disclosed in PTL 3 described above would also be effective, but there is a problem in that amorphous silicon film formation speed using a CVD method is slow. Furthermore, since hazardous gases such as monosilane gas need to be used in a CVD method, complicated exhaust equipment is required.

Next, reducing the number of processes in the manufacturing could be considered as second means for reducing the manufacturing costs of crystalline silicon solar cells. For example, even if the process of PTL 2 described above is taken as an example, at least the processes of 1) forming an amorphous silicon film, 2) polycrystallizing the amorphous silicon film to be a polycrystalline silicon film, 3) doping the polycrystalline silicon film with a dopant, and 4) activating the doped dopant by annealing, are required in the manufacturing of a polycrystalline silicon solar cell.

### Solution to Problem

In the present invention, an amorphous silicon film is formed using a vapor deposition method with doped silicon as a vapor deposition material, and the formed amorphous silicon film is polycrystallized to obtain a polycrystalline silicon film of a polycrystalline silicon solar cell.

In addition, in the present invention, both of crystallizing the amorphous silicon film and activating the doped dopant are simultaneously performed in one process. The crystallizing and activating are in the known manufacturing method of a polycrystalline solar cell. In this way, the manufacturing costs of a polycrystalline solar cell of the present invention can be reduced by simplifying the manufacturing method.

That is, the method of manufacturing a polycrystalline silicon solar cell panel of the present invention includes a process of forming an amorphous silicon film using a vapor deposition method with doped silicon as a vapor deposition material, and a process of performing activation of the doped dopant while polycrystallizing the amorphous silicon film using plasma irradiation. As a result of this, it is possible to obtain a polycrystalline silicon film in which pn junctions are formed by using fewer processes and in less time, and therefore it is possible to provide a polycrystalline silicon solar cell panel that is capable of being manufactured at a low-cost.

More specifically, the present invention relates to the manufacturing method of a polycrystalline solar cell panel and polycrystalline solar cell panel indicated below.

(1) A manufacturing method for a polycrystalline silicon solar cell panel includes: a process of forming an amorphous silicon film on a substrate using a vapor deposition method that uses an n-type doped silicon as a vapor deposition material; a process of plasma-doping a surface layer of the amorphous silicon film with a p-type dopant; and a process of melting the amorphous silicon film by scanning the plasma-doped amorphous silicon film with plasma to polycrystallize the amorphous silicon film.

(2) A manufacturing method for a polycrystalline silicon solar cell panel includes a process of forming an amorphous silicon film on a substrate using a vapor deposition method that uses a p-type doped silicon as a vapor deposition material; a process of plasma-doping a surface layer of the amorphous silicon film with an n-type dopant; and a process of melting the amorphous silicon film by scanning the plasma-doped amorphous silicon film with plasma to polycrystallize the amorphous silicon film.

### Advantageous Effects of Invention

According to the present invention it is possible to form a polycrystalline silicon film in which pn junctions are formed using fewer processes and in less time, and therefore an inexpensive polycrystalline solar cell panel is provided.

### BRIEF DESCRIPTION OF DRAWINGS

FIG. 1A is a process chart illustrating a process flow according to an embodiment in which a polycrystalline silicon film having a pn junction is formed on a substrate;

FIG. 1B is a process chart illustrating a process flow according to an embodiment in which a polycrystalline silicon film having a pn junction is formed on an electrode formed on a substrate;

FIG. 2A is a process chart illustrating a process flow according to an embodiment in which a substrate and double sided electrode type solar cell panel is manufactured from a laminate comprising a conductive substrate and a polycrystalline silicon film;

FIG. 2B is a process chart illustrating a process flow according to an embodiment in which a substrate and double sided electrode type solar cell panel is manufactured from a laminate comprising a transparent insulating substrate, an electrode and a polycrystalline silicon film;

FIG. 2C is a process chart illustrating a process flow according to an embodiment in which a superstrate and double sided electrode type solar cell panel is manufactured from a laminate comprising a transparent insulating substrate, an electrode and a polycrystalline silicon film;

FIG. 2D is a process chart illustrating a process flow according to an embodiment in which a superstrate and rear-contact type solar cell panel is manufactured from a laminate comprising a transparent insulating substrate and a polycrystalline silicon film;

FIG. 3 is a schematic view of an atmospheric-pressure plasma apparatus used to change an amorphous silicon film to a polycrystalline silicon film in an embodiment of the present invention;

FIG. 4 is a schematic view illustrating a state in which a silicon ingot of the related art is cut by a wire; and

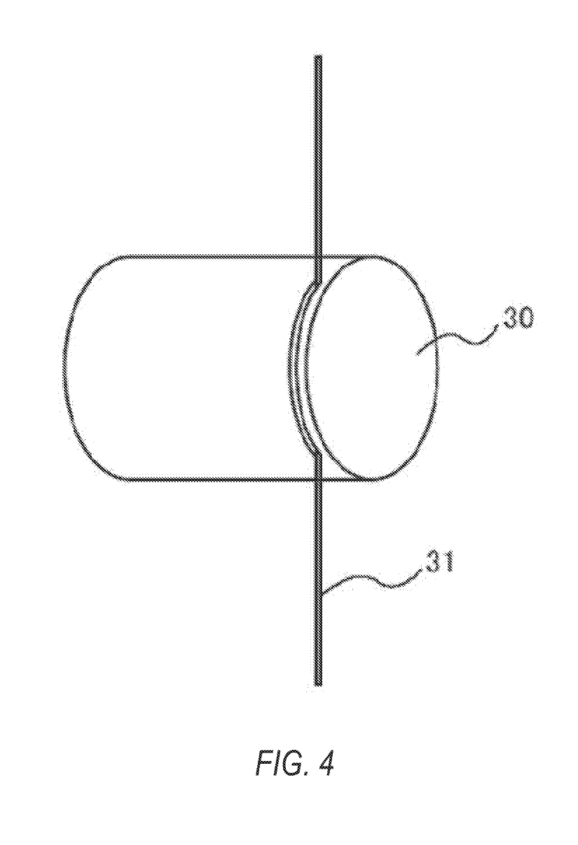

FIG. 5 is a schematic view of an apparatus for manufacturing a polycrystalline silicon plate of the related art.

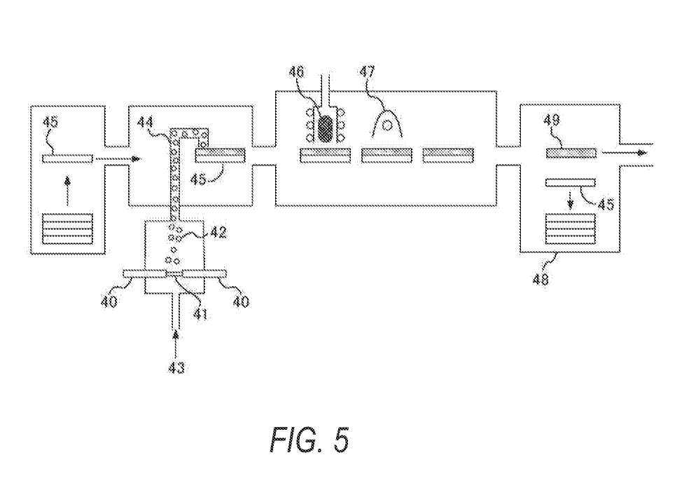

### DESCRIPTION OF EMBODIMENTS

Hereinafter, embodiments of the present invention will be described with reference to the drawings.

The manufacturing methods of a polycrystalline silicon solar cell panel of the present invention includes a process of forming either an n-type or p-type doped amorphous silicon film, a process of doping a surface layer of the amorphous silicon film with either an n-type dopant or p-type dopant, and a process of polycrystallizing the amorphous silicon film doped with the dopant to obtain a polycrystalline silicon film. The polycrystalline silicon film obtained in such a manner can be used as a silicon film for a polycrystalline silicon solar cell.

1. Formation of the Polycrystalline Silicon Film

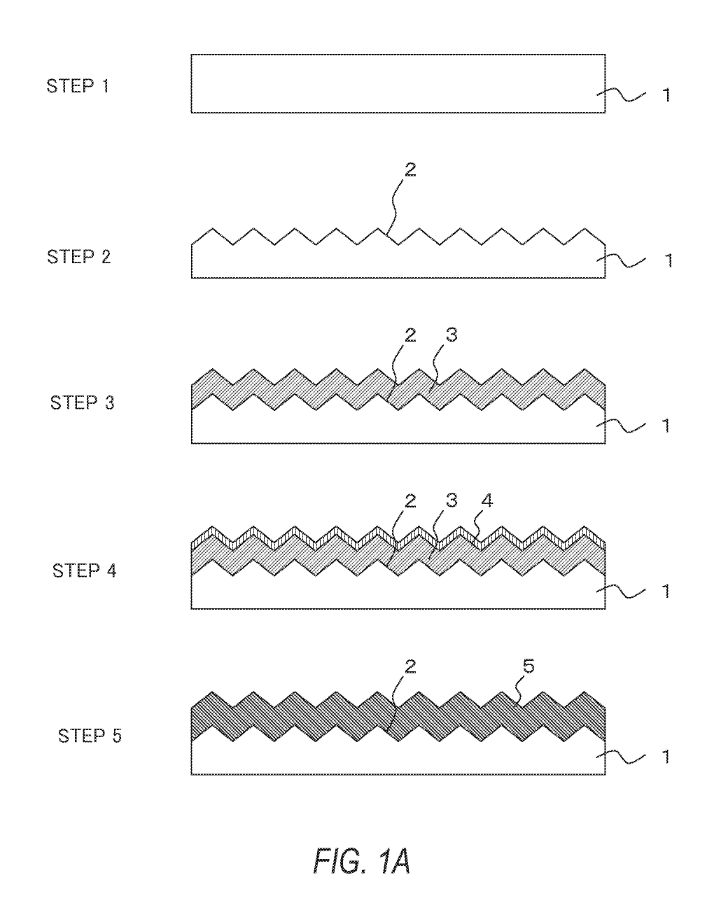

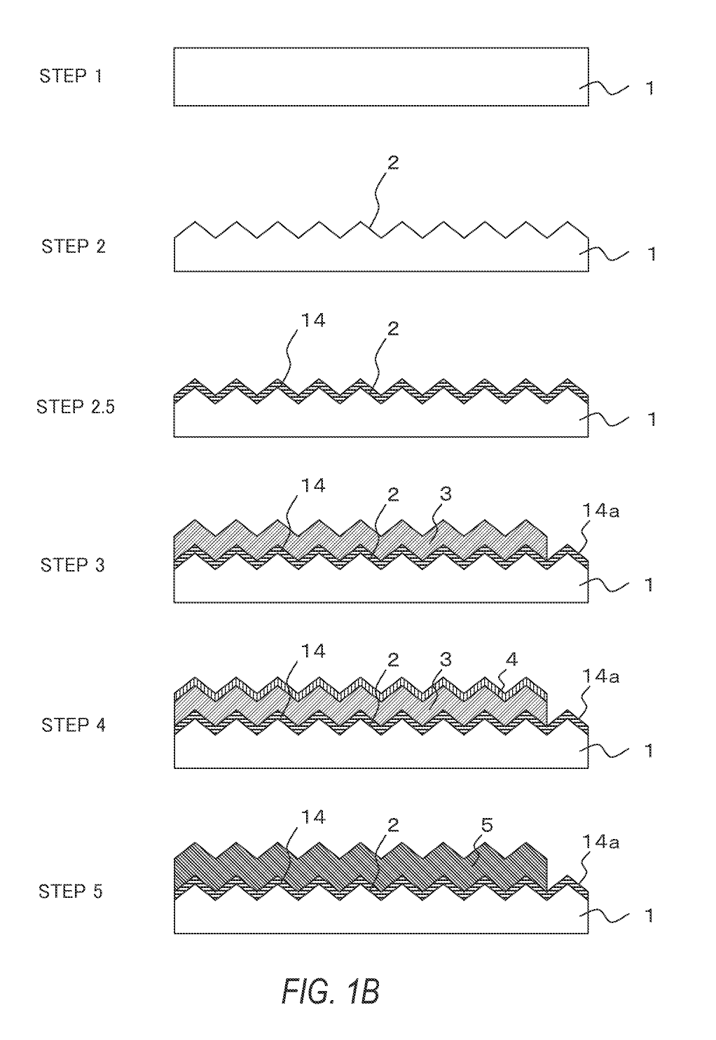

Process flows of manufacturing the solar cell panel of the present invention are illustrated in FIGS. 1A and 1B. In the flows illustrated in FIGS. 1A and 1B, a polycrystalline silicon film in which pn junctions are formed, is formed on a substrate. FIG. 1A illustrates a flow (first film formation flow) in which a polycrystalline silicon film is formed directly on substrate 1 and FIG. 1B illustrates a flow (second film formation flow) in which a polycrystalline silicon film is formed on electrode film 14 formed on the surface of substrate 1.

1-1. First Film Formation Flow

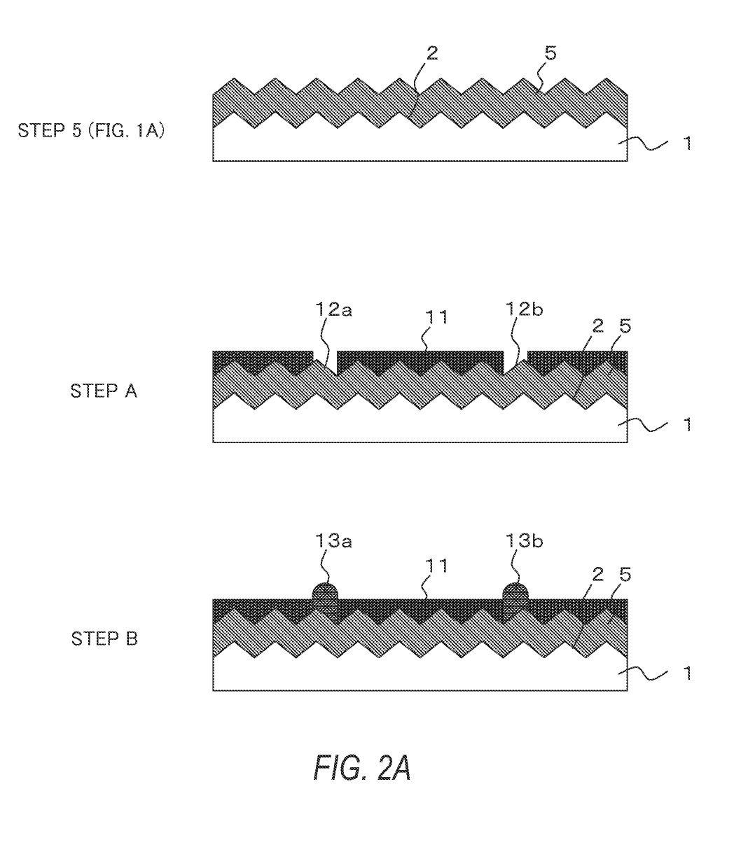

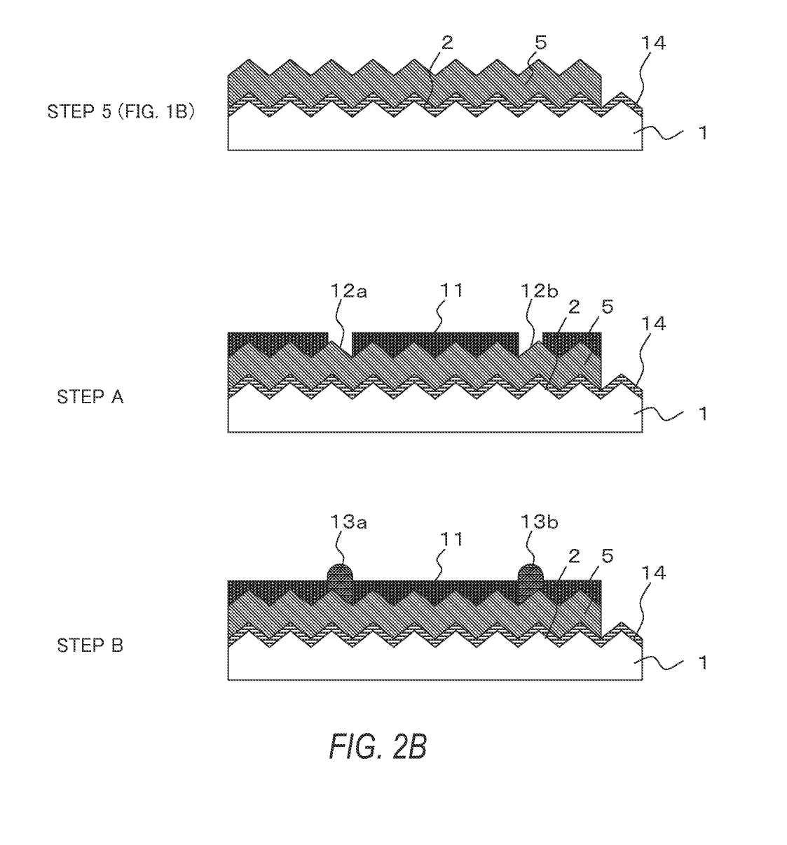

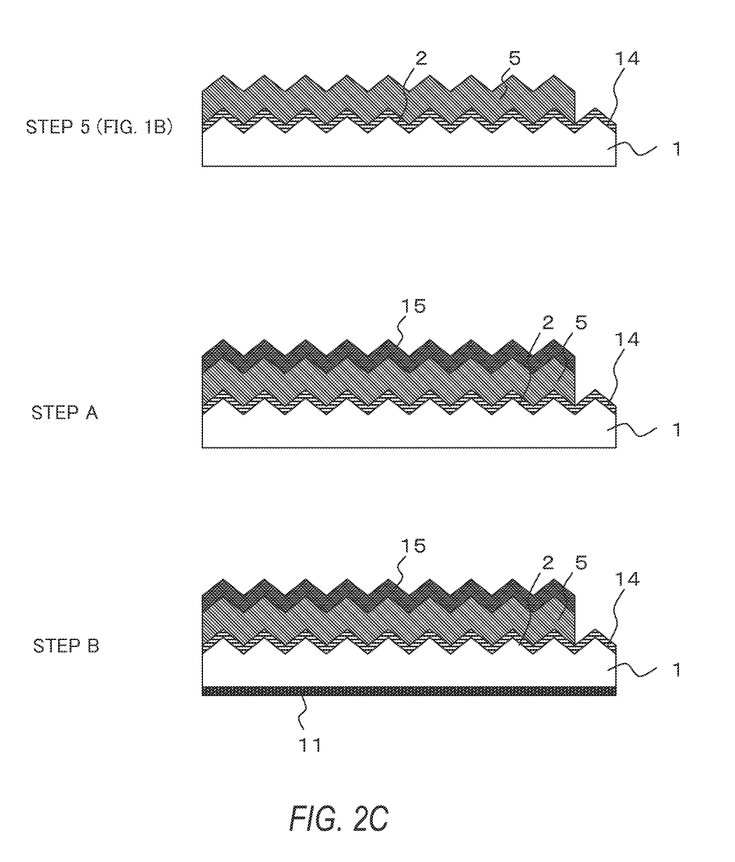

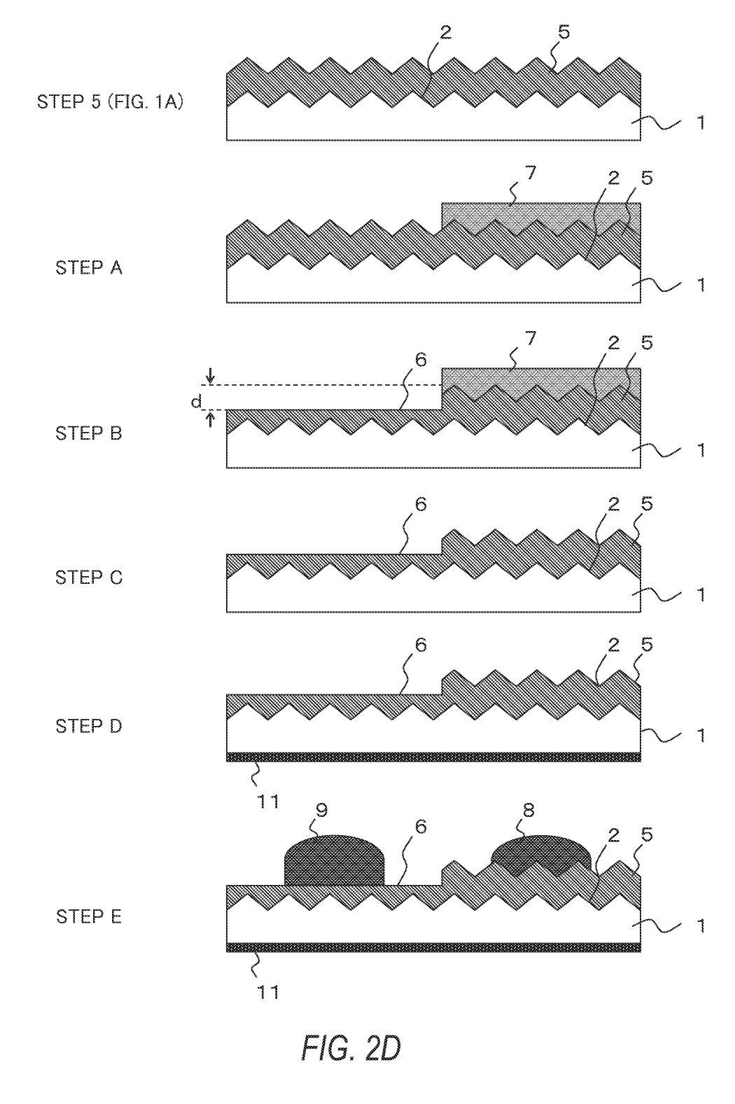

In Step 1 in FIG. 1A, substrate 1 is prepared. Substrate 1 may be an insulating transparent substrate such as glass or quartz, or may be a conductive substrate such as metal. In a case where substrate 1 is an insulating transparent substrate, it is possible to configure a superstrate-type rear surface electrode solar cell (refer to FIG. 2D) and in a case where substrate 1 is a conductive substrate it is possible to configure a substrate and double sided electrode type solar cell (refer to FIG. 2A). Superstrate-type refers to a solar cell in which light is taken into a polycrystalline silicon film through substrate 1. Substrate-type refers to a solar cell in which light is taken into a polycrystalline silicon film from a side opposite substrate 1.

In Step 2 in FIG. 1A, texture 2 is formed on a surface of substrate 1. Among the surfaces of substrate 1, texture 2 is formed on a surface on which a polycrystalline silicon film is to be formed. If substrate 1 is a glass substrate, texture 2 may be formed by treating a surface of the glass substrate with a chemical solution containing hydrogen fluoride to form a concavo-convex shape. In addition, if substrate 1 is a glass substrate, texture 2 may be formed by plasma into which fluorine gas has been incorporated. On the other hand, if substrate 1 is a conductive substrate such as metal (for example, stainless steel), it is possible to form texture 2 by pressing the top of the substrate into a mold (for example, a cylindrical mold) that has concavity and convexity on a surface thereof while rotationally scanning the mold.

In Step 3 in FIG. 1A, amorphous silicon film 3 is formed on a formation surface of texture 2 of substrate 1 using a vapor deposition method. Vapor deposition may be performed using a vapor deposition apparatus.

Film formation according to the vapor deposition method is performed using silicon pellets or silicon powder as a vapor deposition material. The vapor deposition material is either p-type or n-type doped silicon. The technique used to dope silicon so as to obtain the vapor deposition material is not limited. For example, p-type doping may be performed using boron, a boron compound, or the like, and n-type doping may be performed using phosphorus or arsenic, or a compound containing phosphorus or arsenic.

Generally, it is preferable that the concentration of the dopant in the vapor deposition material be in a range from 1×10¹⁶/cm³ to 1×10²⁰/cm³.

If p-type doped silicon pellets or silicon powder is used as the vapor deposition material, p-type amorphous silicon film 3 can be formed by a vapor deposition method; and if n-type doped silicon pellets or silicon powder is used as the vapor deposition material, n-type amorphous silicon film 3 can be formed.

In the technique for film formation according to the vapor deposition method, an n-type or p-type doped silicon (silicon pellets or silicon powder) as the vapor deposition material is supplied to a melting pot installed inside a vacuum chamber of a vapor deposition apparatus, and the supplied silicon as the vapor deposition material is irradiated with electron beams or ion beams. An amorphous silicon film is formed on substrate 1 which has been disposed to face the melting pot inside the vacuum chamber. For example, as conditions for film formation, the pressure inside the vacuum chamber is reduced to 10⁻⁴ Pa or less, and several kW of electricity is input into the electric power supply for vapor deposition.

Although the thickness of amorphous silicon film 3 formed on the formation surface of texture 2 of substrate 1 using a vapor deposition method is not particularly limited, it is preferably in a range from 10 μm to 100 μm and may for example, be approximately 50 μm.

In Step 4 in FIG. 1A, a surface layer of amorphous silicon film 3 formed using a vapor deposition method is doped with a dopant to form doping layer 4. In a case where amorphous silicon film 3 is an n-type amorphous silicon film, doping is performed with a p-type dopant to form p-type doping layer 4. On the other hand, in a case where amorphous silicon film 3 is a p-type amorphous silicon film, doping is performed with an n-type dopant to form n-type doping layer 4.

Examples of p-type dopants include boron and boron compounds. Diborane (B₂H₆) and the like are representative examples of a boron compound. Examples of n-type dopants include gases or compounds containing phosphorus or arsenic. Phosphine (PH₃) and the like are a representative examples of a phosphorus compound, and arsine (AsH₃) and the like are representative examples of an arsenic compound.

The doping with a dopant can be performed using plasma. Doping using plasma refers to a technique in which dopant gas is introduced into a vacuum apparatus, the dopant is ionized by plasma generated using high frequency, and the ionized dopant is introduced into the surface layer of amorphous silicon film 3.

By performing doping with a dopant using plasma, it is possible to reduce the thickness of the surface layer of amorphous silicon film 3 into which the dopant is introduced. That is, by using plasma, it is possible to achieve a high concentration of dopant in a thin surface layer.

In a case where B₂H₆ gas is used as a p-type dopant, p-type doping is performed by: introducing B₂H₆ gas (0.5% He dilution) and Ar gas into a chamber of a vacuum apparatus; ionizing the boron with plasma generated under 13.56 MHz high frequency; and introducing the ionized boron into a surface layer of an n-type silicon sputter film. The pressure inside the vacuum during doping may be adjusted as appropriate, and it may be set to approximately 0.5 Pa. The flow rate of the B₂H₆ gas may be set to 100 sccm, and the flow rate of the Ar gas may be set to 100 sccm. The during time necessary for doping may be 30 to 60 seconds.

On the other hand, in order to perform plasma-doping with an n-type dopant, the same sequence as that of the case of the p-type dopant using B₂H₆ gas may be performed using PH₃ or AsH₃ gas as an n-type dopant.

In addition, solid boron may be used as a p-type dopant in order to dope a surface layer of n-type amorphous silicon film 3 with a p-type dopant. In a case where solid boron is used, p-type doping is performed by: placing solid boron inside a chamber of a vacuum; introducing Ar gas (the flow rate of the Ar gas is 100 sccm); ionizing the solid boron with plasma generated under high frequency; and introducing the ionized boron into a surface layer of n-type amorphous silicon film 3. The pressure inside the vacuum during doping may be adjusted as appropriate, and it may be set to approximately 10 Pa. The during time necessary for doping may be 30 to 60 seconds.

The dose amount of ionized boron introduced into n-type amorphous silicon film 3 may be adjusted as appropriate to be capable of forming the pn junctions required for a solar cell, it was experimentally found that it is preferably in a range from 1×10¹⁷/cm³ to 1×10¹⁹/cm³ in order to increase the photoelectric conversion efficiency of the obtained solar cell.

Additionally, in order to perform n-type doping using solid material, the same process as that of the case of the p-type dopant using solid boron may be performed using phosphate glass (P₂O₅).

In Step 5 in FIG. 1A, amorphous silicon film 3 including doping layer 4 is polycrystallized by being irradiated with plasma. By this irradiation, amorphous silicon film 3 is melted and then cooled immediately after melting so as to form polycrystalline silicon film 5 from amorphous silicon film 3. A pn junction is formed in polycrystalline silicon film 5.

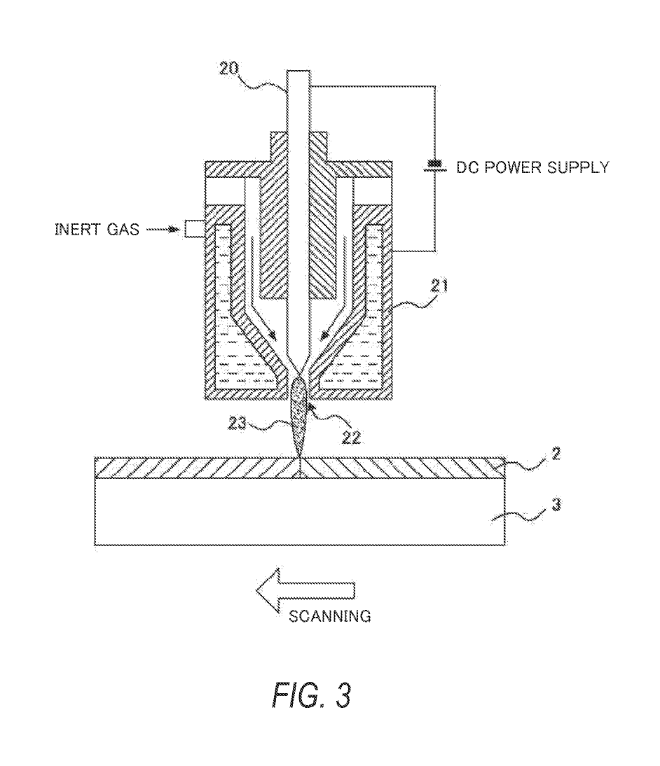

It is preferable that the plasma with which amorphous silicon film 3 is irradiated be atmospheric-pressure plasma. Atmospheric-pressure plasma is plasma that is irradiated in an atmospheric-pressure environment. Irradiation of atmospheric-pressure plasma can be performed using an atmospheric-pressure plasma apparatus. An outline of an atmospheric-pressure plasma apparatus that can be used in such a circumstance is illustrated in FIG. 3. The atmospheric-pressure plasma apparatus illustrated in FIG. 3 includes cathode 20 and anode 21. Plasma spray port 22 is provided at anode 21. Since arc discharge is generated when a DC voltage is applied between cathode 20 and anode 21, by introducing inert gas (nitrogen gas or the like), plasma 23 can be jetted out from plasma spray port 22. This kind of atmospheric-pressure plasma apparatus is disclosed, for example, in Japanese Patent Application Laid-Open No. 2008-53632.

Substrate 1 (refer to Step 4 in FIG. 1A) on which amorphous silicon film 3 including doping layer 4 is formed, is loaded onto a stage (not shown) of the atmospheric-pressure plasma apparatus, the stage being movable along XYZ axes. An atmospheric-pressure plasma is scanned from one end of a surface of amorphous silicon film 3 to the other end so as to subject amorphous silicon film 3 to a heat treatment. The areas of amorphous silicon film 3 (including doping layer 4 as the surface layer) that have been irradiated with plasma 23 melt.

By suitably controlling the temperature of atmospheric-pressure plasma 23 on the surface of amorphous silicon film 3, the molten state of amorphous silicon film 3 including doping layer 4 is adjusted. It is possible to arbitrarily control the temperature of atmospheric-pressure plasma 23 on the surface of amorphous silicon film 3 by adjusting the power of the power supply of the atmospheric-pressure plasma, the space between spray port 22 and amorphous silicon film 3, and the like.

The temperature of the atmospheric-pressure plasma is generally 1×10⁴° C. or more, and it is preferable that the temperature of the atmospheric-pressure plasma be adjuster so that the temperature of the tip of plasma spray port 22 is approximately 2×10³° C. Plasma spray port 22 is disposed apart from amorphous silicon film 3 by approximately 5 mm. The injection power is set as 20 kW, and plasma 23 is pushed out by inert gas to be sprayed onto amorphous silicon film 3. It is preferable that irradiation area of plasma 23 from spray port 22 on the substrate surface has a diameter of 40 mm.

It is preferable that a rate of the scanning of the atmospheric-pressure plasma be set as 100 mm/sec to 2000 mm/sec, and for example, is set as approximately 1000 mm/sec. If the scanning rate is 100 mm/sec or less, substrate 1 as a base can melt, and an adverse effect is brought about in obtained polycrystalline silicon film 5. In addition, if the scanning rate is 2000 mm/sec or more, only the surface layer of amorphous silicon film 3 can melt, and there are cases where it is not possible to melt the entire of amorphous silicon film 3. In addition, the apparatus system required in order to scan at a speed of 2000 mm/sec or more, is complicated.

Amorphous silicon film 3 including doping layer 4 is irradiated with atmospheric-pressure plasma to melt, and thereafter, to cool rapidly. By doing so, amorphous silicon film 3 changes to polycrystalline silicon film 5 with a small crystal grain size. At this time, it is preferable that molten amorphous silicon film 3 be cooled as rapidly as possible so that the crystal grain size of the polycrystal becomes 0.05 μm or less.

In addition, a small amount of hydrogen gas may be mixed with the inert gas that pushes atmospheric-pressure plasma 23 out. By mixing the small amount of hydrogen gas, it is possible to remove an oxide film formed on the surface of amorphous silicon film 3, and it is possible to obtain polycrystalline silicon film 5 with few crystal defects.

As described above, in the present invention, amorphous silicon film 3 including doping layer 4 formed on a surface of substrate 1 is heated to melt with atmospheric-pressure plasma, and thereafter cool to undergo polycrystallization. On the other hand, melting the bulk silicon disposed on a surface of substrate 1 with atmospheric-pressure plasma, which is a known method in the related art, is difficult. And also, it is required for the known method to melt with high-temperature plasma in a vacuum environment. In comparison with a case where high-temperature plasma is used in a vacuum environment, it is possible to quickly melt and polycrystallize a large area of amorphous silicon film 3 by using atmospheric-pressure plasma.

Furthermore, the present invention is also characterized by polycrystallizing amorphous silicon film 3 after forming doping layer 4 by doping the surface layer of amorphous silicon film 3 with a dopant. As a result of this, in the process of polycrystallizing amorphous silicon film 3, the dopant included in doping layer 4 is simultaneously activated so as to obtain polycrystalline silicon film 5 in which pn junction is formed.

On the other hand, a conventional process in which the dopant is doped after polycrystallizing an amorphous silicon film, and then a treatment (annealing) to form pn junctions by activating the dopant after doping has been performed. As such, in addition to the polycrystallization process, a process of treatment (annealing) process was necessary for the conventional process. In contrast, the present invention is based on the new knowledge that it is possible to activate the dopant included in doping layer 4, which is the surface layer of amorphous silicon film 3, through the polycrystallization process using atmospheric-pressure plasma.

The present embodiment uses an atmospheric-pressure plasma apparatus that uses DC arc discharge as an atmospheric-pressure plasma apparatus, but the atmospheric-pressure plasma apparatus may have a different system. Examples of different systems include an ICP system or a CCP system that use RF discharge under high frequency (for example, 13.56 MHz).

In addition, in the present embodiment, the head unit of the atmospheric-pressure plasma apparatus from which the plasma is ejected was configured as a spot-type but can also be configured as a linear-type. When the head unit is configured as a linear slit type, it is possible to irradiate substrate 1 with linear plasma. If the length of the linear plasma is configured to be greater than one side of substrate 1, it leads to a reduction of the process time since the annealing process can be completed by single scanning in one direction.

1-2. Second Film Formation Flow

A process flow in which electrode layer 14 is formed on substrate 1′, and then a polycrystalline silicon film having a pn junction is formed on electrode layer 14, is illustrated in FIG. 1B.

In Step 1 in FIG. 1B, resistant and transparent substrate 1′ made of glass, quartz, or the like is prepared.

In Step 2 in FIG. 1B, texture 2 is formed on a surface of substrate 1′ in the same manner as Step 2 of FIG. 1A. Since a method of formation of texture 2 is the same as that in Step 2 of FIG. 1A, the description thereof is omitted.

In Step 2.5 in FIG. 1B, electrode layer 14 is formed on substrate 1′. Electrode layer 14 will constitute one of the electrodes of a solar cell. In a case where electrode layer 14 is made of metal (for example, Cr, Mo, Ta, W, or the like), it is possible to configure a substrate-type solar cell (refer to FIG. 2B) and in a case where electrode layer 14 is a transparent conductor (for example, ITO, ZnO, or the like), it is possible to configure a superstrat and double sided electrode type solar cell (refer to FIG. 2C). Vacuum processes such as vapor deposition and sputtering may be used for the formation of electrode layer 14. Alternatively, coating processes such as a die-coating method or a spray method may be used.

In Step 3 in FIG. 1B, amorphous silicon film 3 is formed on electrode layer 14 using a vapor deposition method. The same vapor deposition method as that of the vapor deposition method in Step 3 of FIG. 1A may be used for the vapor deposition method of amorphous silicon film 3. In addition, in Step 4 in FIG. 1B, doping layer 4 is formed using plasma-doping. A plasma-doping method may be the same as that of the plasma-doping in Step 4 of FIG. 1A.

However, as shown in Step 4 in FIG. 1B, exposed surface 14a which is a portion of electrode layer 14 is not covered by amorphous silicon film 3. Exposed surface 14a is an electrode terminal for extracting electricity from the solar cell. A method for exposing exposed surface 14a is not limited, and for example, the film formation of amorphous silicon film 3 (Step 3) and the formation of doping layer 4 (Step 4) may be performed while exposed surface 14a is masked by a metal plate or the like. Alternatively, exposed surface 14a may be exposed by: performing the film formation of amorphous silicon film 3 (Step 3) and the formation of doping layer 4 (Step 4) over the entire surface of electrode layer 14; masking amorphous silicon film 3 other than exposed surface 14a with a resist or the like; and then removing a silicon layer formed on exposed surface 14a using a method such as wet etching or dry etching.

In Step 5, amorphous silicon film 3 including doping layer 4 is melted by irradiation with plasma in the same manner as that in FIG. 1A, and is cooled immediately so as to be polycrystallized. Since a method of formation of polycrystalline silicon film 5 is the same as the process flow of FIG. 1A, the description thereof is omitted.

2. Solar Cell Manufacturing Process Flow

Hereinafter, process flows of respective methods of processing substrate 1 on which polycrystalline silicon film 5 is formed to manufacture a solar cell will be described with reference to the FIGS. 2A to 2D.

2-1. Substrate and Double Sided Electrode Type Solar Cell Including Conductive Substrate (FIG. 2A)

The solar cell illustrated in Step B of FIG. 2A is referred to as a substrate and double sided electrode type solar cell that uses a conductive substrate. This solar cell includes one electrode (surface electrode) on a light receiving surface, and the other electrode (rear surface electrode) on a rear surface, conductive substrate 1 serving as the other electrode.

In Step A of FIG. 2A, antireflective layer 11 is formed on a surface of polycrystalline silicon film 5 obtained by Step 5 of FIG. 1A. Antireflective layer 11 is made of silicon oxide (SiOₓ), silicon nitride (SiNₓ) or the like, but the material thereof are not particularly limited. The method of formation thereof may be a vacuum process such as vapor deposition method or a sputtering method, or may be a coating process such as a die-coating method or a spray method.

A portion of the surface of polycrystalline silicon film 5 is not covered by antireflective layer 11, thereby forming exposed surfaces 12a and 12b. A method for exposing exposed surfaces 12a and 12b is not limited. For example, the formation of antireflective layer 11 (Step A) may be performed while exposed surfaces 12a and 12b are masked by a metal plate or the like. Alternatively, exposed surfaces 12a and 12b is formed by: forming antireflective layer 11 over the entire surface of polycrystalline silicon film 5; masking antireflective layer 11 other than that on exposed surfaces 12a and 12b with a resist or the like; removing a part of antireflective layer 11 on exposed surfaces 12a and 12b using a method such as wet etching or dry etching.

Next, in Step B of FIG. 2A, surface electrodes 13a and 13b (electric wiring) are respectively formed on exposed surfaces 12a and 12b. Examples of the materials of the surface electrodes include silver (Ag), aluminum (Al), copper (Cu), solder material and the like, but the materials thereof are not particularly limited as long as they are conductive. In addition, the method of formation thereof is not particularly limited, and for example, a screen printing method may be adopted.

In this manner, it is possible to obtain a substrate and double sided electrode solar cell that uses a conductive substrate. That is, sunlight is taken into polycrystalline silicon film 5 through antireflective layer 11, and electricity is extracted through surface electrodes 13a and 13b and substrate 1 that acts as a rear surface electrode.

A solar cell with this configuration has a feature of leading to a reduction in materials costs and the number of processes, since it is possible to cause the substrate to act as a rear surface electrode.

2-2. Substrate and Double Sided Electrode Solar Cell Including Transparent Insulating Substrate (FIG. 2B)

The solar cell illustrated in Step B of FIG. 2B is referred to as a substrate and double sided electrode solar cell that uses a transparent insulating substrate. This solar cell includes one electrode (surface electrode) on a light receiving surface, and the other electrode (metal rear surface electrode) on a rear surface side, electrode layer 14 formed on substrate 1′ serving as the other electrode.

In Step A of FIG. 2B, antireflective layer 11 is formed on a surface of polycrystalline silicon film 5 obtained by Step 5 of FIG. 1B. Antireflective layer 11 is made of silicon oxide (SiOₓ), silicon nitride (SiNₓ) or the like, and the material thereof are not particularly limited. In addition, the method of formation thereof may be a vacuum process such as vapor deposition method or a sputtering method, or may be a coating process such as a die-coating method or a spray method.

A portion of the surface of polycrystalline silicon film 5 and exposed surface 14a of a metal electrode are not covered by antireflective layer 11, thereby forming exposed surfaces 12a and 12b and exposed surface 14a of the metal electrode. A method for exposing exposed surfaces 12a and 12b is not limited. For example, antireflective layer 11 may be formed while exposed surfaces 12a and 12b and exposed surface 14a of the metal electrode are masked by a metal plate, or the like. Alternatively, exposed surfaces 12a and 12b is formed by: forming antireflective layer 11 over the entire surface of polycrystalline silicon film 5 and exposed surface 14a of the metal electrode; masking areas other than the exposed surfaces with a resist or the like; removing a part of antireflective layer 11 on exposed surfaces 12a and 12b and on exposed surface 14a of the metal electrode using a method such as wet etching or dry etching.

Next, in Step B of FIG. 2B, surface electrodes 13a and 13b (electric wiring) are formed on exposed surfaces 12a and 12b. Examples of the material of the surface electrodes include silver (Ag), aluminum (Al), copper (Cu), solder material and the like, and the materials thereof are not particularly limited as long as they are conductive. In addition, the method of formation thereof is not particularly limited, and for example, a screen printing method may be adopted.

In this manner, it is possible to obtain a substrate and double sided electrode type solar cell that uses a transparent insulating substrate. That is, sunlight is taken into polycrystalline silicon film 5 through antireflective layer 11, and electricity is extracted through surface electrodes 13a and 13b and electrode layer 14 that acts as a rear surface electrode.

In a solar cell with this configuration, the material properties of the rear surface electrode are not limited to the material of the substrate, and thus it is possible to select the optimum material for the rear surface electrode. Therefore, it is possible to improve the contact property of the polycrystalline silicon film with the rear surface electrode, and such a solar cell is characterized by bringing about an improvement in the conversion efficiency of a solar cell unit.

2-3. Superstrate and Double Sided Electrode Type Solar Cell including Transparent Insulating Substrate (FIG. 2C)

The solar cell illustrated in Step B of FIG. 2C is referred to as a superstrate and double sided electrode type solar cell that uses a transparent insulating substrate. This solar cell includes one electrode on a light receiving surface, and the other electrode on a rear surface, the substrate side being the light receiving surface. More specifically, transparent electrode layer 14 arranged on the light receiving surface of substrate 1′ serves as the one electrode, and electrode layer 15 arranged on polycrystalline silicon film 5 serves as the rear surface electrode.

In Step A of FIG. 2C, rear surface electrode layer 15 is formed on a surface of polycrystalline silicon film 5 obtained by Step 5 of FIG. 1B. Rear surface electrode layer 15 is made of silver (Ag), aluminum (Al), copper (Cu), or the like, and the material thereof is not particularly limited. In addition, the method of formation thereof may be a vacuum process such as vapor deposition method or a sputtering method, or may be a coating process such as a die-coating method or a spray method.

Exposed surface 14a of transparent electrode layer 14 is not covered by rear surface electrode layer 15, thereby forming exposed surface 14a. A method for forming exposed surface 14a of transparent electrode layer 14 is not limited, and for example, rear surface electrode layer 15 may be formed while exposed surface 14a of transparent electrode layer 14 is masked by a metal plate, or the like. Alternatively, exposed surface 14a is formed by: forming rear surface electrode layer 15; masking areas other than exposed surface 14a with a resist or the like; removing rear surface electrode layer 15 formed on exposed surface 14a using a method such as wet etching or dry etching.

Next, in Step B of FIG. 2C, antireflective layer 11 is formed on the surface of the light receiving surface of substrate 1′. Antireflective layer 11 is made of silicon oxide (SiOₓ), silicon nitride (SiNₓ) or the like, and the material thereof is not particularly limited. In addition, the method of formation thereof may be a vacuum process such as vapor deposition method or a sputtering method, or may be a coating process such as a die-coating method or a spray method.

In a superstrate and double sided electrode type solar cell that uses a transparent insulating substrate, sunlight is taken into polycrystalline silicon film 5 through antireflective layer 11, substrate 1′ and transparent electrode layer 14. In addition, generated electricity is extracted through transparent electrode layer 14 and rear surface electrode layer 15. Since an electrode that blocks light is not present on the light receiving surface, the amount of light received is increased, and therefore a solar cell with this configuration has a feature of leading to an improvement in the conversion efficiency of a solar cell.

2-4. Superstrate and Rear Contact Type Solar Cell Including Transparent Insulating Substrate (FIG. 2D)

The solar cell illustrated in FIG. 2D is referred to as a superstrate and rear contact type solar cell that uses a transparent insulating substrate. This solar cell include no electrode on a light receiving surface, and includes both an anode and a cathode on a surface opposite the light receiving surface.

Steps A to C of FIG. 2D are a flow of partial etching of a portion of polycrystalline silicon film 5 obtained in by Step 5 of FIG. 1A in a depth direction.

The partial etching of polycrystalline silicon film 5 can for example, be performed using mask 7. Mask 7 can be made of a resist that is used in known semiconductor processes. That is, in Step A of FIG. 2D, a resist is coated onto the surface of polycrystalline silicon film 5 using an arbitrary technique such as a spin method, a spray method, a screen printing method or an inkjet method, and then the resist film is patterned as required to form mask 7.

In Step B, exposed surface 6 is exposed by removing a part of the surface layer of polycrystalline silicon film 5 that is not covered by mask 7 using etching. The etching of polycrystalline silicon film 5 may be conducted by for example, by wet etching using a solution containing hydrogen fluoride (HF) and nitric acid (HNO₃) as an etchant, but is not particularly limited. The thickness (etching depth d) of the surface layer of polycrystalline silicon film 5 to be removed may be selected such that doping layer 4 formed in Step 4 of FIG. 1A can be removed. That is, the thickness may be selected such that it is capable of removing an area in which the dopant contained in doping layer 4 is diffused. By doing so, it is capable of making a doping type of the surface of polycrystalline silicon film 5 and a doping type of exposed surface 6 different from each other.

The etching depth d can be set as appropriate depending on the doping technique, the type of dopant and the like. In a case where a boron-containing gas is used as p-type dopant, when the dopant diffusion area is considered in the light of the characteristics as solar cell, the etching depth d can be generally 50 nm or more, and for example, is approximately 100 nm. In addition, the upper limit of the etching depth d is approximately 10 μm.

Mask 7 is removed in Step C.

Next, in Step D, antireflective layer 11 is formed on the light receiving surface of substrate 1. Antireflective layer 11 is made of silicon oxide (SiOₓ), silicon nitride (SiNₓ) or the like, and the material thereof is not particularly limited. In addition, the method of formation thereof may be a vacuum process such as vapor deposition method or a sputtering method, or may be a coating process such as a die-coating method or a spray method.

In addition, an insulating film (not shown) that covers the end portion of substrate 1 may be formed. By doing so, it is possible to prevent deteriorations in the electrical characteristics of the end portion. The insulating film may be made of silicon oxide (SiOₓ), silicon nitride (SiNₓ) or the like, and can be formed using a sputtering method.

Thereafter, in Step E, one electrode 8 and the other electrode 9 are arranged. First electrode 8 is formed on the remaining surface of polycrystalline silicon film 5 that was not removed by etching. Second electrode 9 is disposed on exposed surface 6 that was exposed by partial etching. Examples of the materials of the electrode include silver (Ag), aluminum (Al), copper (Cu), solder material and the like, and the materials thereof are not particularly limited as long as they are conductive.

In this manner, it is possible to obtain a superstrate and rear contact type solar cell that uses a transparent insulating substrate. That is, sunlight is taken into polycrystalline silicon film 5 through substrate 1, and electricity is extracted through electrode 8 and electrode 9.

Since no electrode that blocks light is present on the light receiving surface, the amount of light received is increased, and a solar cell with this configuration has a feature of leading to an improvement in the conversion efficiency of a solar cell.

### INDUSTRIAL APPLICABILITY

The present invention is suitable for providing affordable and efficient large-sized solar cell panels.

### Reference Signs List

1, 1′ Substrate

2 Texture

3 Amorphous silicon film

4 Doping layer

5 Polycrystalline silicon film

11 Antireflective layer

12a Exposed surface of polycrystalline silicon film

12b Exposed surface of polycrystalline silicon film

13a Surface electrode

13b Surface electrode

14 Electrode layer

14a Exposed surface of electrode layer

15 Rear surface electrode layer

1. A manufacturing method for a polycrystalline silicon solar cell panel comprising:
forming an amorphous silicon film on a substrate using a vapor deposition method that uses an n-type doped silicon as a vapor deposition material;
plasma-doping a surface layer of the amorphous silicon film with a p-type dopant; and
melting the amorphous silicon film by scanning the plasma-doped amorphous silicon film with a plasma to polycrystallize the amorphous silicon film.

2. A manufacturing method for a polycrystalline silicon solar cell panel comprising:
forming an amorphous silicon film on a substrate using a vapor deposition method that uses a p-type doped silicon as a vapor deposition material;
plasma-doping a surface layer of the amorphous silicon film with an n-type dopant; and
melting the amorphous silicon film by scanning the plasma-doped amorphous silicon film with a plasma to polycrystallize the amorphous silicon film.

3. The manufacturing method for a polycrystalline silicon solar cell panel according to claim 1, wherein the substrate includes glass or quartz.

4. The manufacturing method for a polycrystalline silicon solar cell panel according to claim 2, wherein the substrate includes glass or quartz.

5. The manufacturing method according to claim 1, wherein the substrate is a conductive material.

6. The manufacturing method according to claim 2, wherein the substrate is a conductive material.

7. The manufacturing method for a polycrystalline silicon solar cell panel according to claim 1, wherein the plasma is an atmospheric-pressure plasma.

8. The manufacturing method for a polycrystalline silicon solar cell panel according to claim 2, wherein the plasma is an atmospheric-pressure plasma.

9. The manufacturing method for a polycrystalline silicon solar cell panel according to claim 1, wherein a rate of the scanning is 100 mm/sec or more and 2000 mm/sec or less.

10. The manufacturing method for a polycrystalline silicon solar cell panel according to claim 2, wherein a rate of the scanning is 100 mm/sec or more and 2000 mm/sec or less.

11. A polycrystalline silicon solar cell panel obtained through the method according to claim 1.

12. A polycrystalline silicon solar cell panel obtained through the method according to claim 2.
